(19) United States
(12) Patent Application Publication
(10) Pub. No.: US 2025/0125793 A1
(43) Pub. Date: Apr. 17, 2025

(54) Quantum Controller with Modular and Dynamic Pulse Generation and Routing

(71) Applicant: Quantum Machines, Tel Aviv (IL)

(72) Inventors: Yonatan Cohen, Tel Aviv (IL); Nissim Ofek, Tel Aviv (IL); Itamar Sivan, Tel Aviv (IL)

(21) Appl. No.: 18/829,370

(22) Filed: Sep. 10, 2024

Related U.S. Application Data
(63) Continuation of application No. 18/364,848, filed on Aug. 3, 2023, now Pat. No. 12,088,302.
Application No. 18/364,848 is a continuation of application No. 17/541,523, filed on Dec. 3, 2021, now Pat. No. 11,750,179.
Application No. 17/541,523 is a continuation of application No. 16/848,965, filed on Apr. 15, 2020, now Pat. No. 11,245,389.
Application No. 16/848,965 is a continuation of application No. 16/451,683, filed on Jun. 25, 2019, now Pat. No. 10,637,449.
Application No. 16/451,683 is a continuation of application No. 16/199,981, filed on Nov. 26, 2018, now Pat. No. 10,333,503.

(51) Int. Cl. H03K 3/38; G06F 13/36; G06F 15/80; G06F 15/82; G06N 10/40; G06N 10/60; G06N 10/80; H03K 19/195

(52) U.S. Cl. CPC H03K 3/38; G06F 13/36; G06F 15/80; G06F 15/82; G06N 10/40; G06N 10/60; G06N 10/80; H03K 19/195

(57) ABSTRACT

A controller comprises a pulse generation circuit, output management circuitry, and a plurality of outputs configured to connect the controller to a plurality of controlled elements. The pulse generation circuit is configured to generate quantum control pulses. For each control pulse of a plurality of control pulses generated by the pulse generation circuit, the output management circuitry is configured to determine to which of the plurality of outputs to route the control pulse such that a first of the plurality of control pulses is routed to a first of the plurality of controlled elements and a second of the plurality of control pulses is routed to a second of the plurality of control elements.

### PRIORITY CLAIM

This application is a continuation of U.S. patent application Ser. No. 16/451,683 filed Jun. 25, 2019 (now U.S. Pat. No. 10,637,449), which is a continuation of Ser. No. 16/199,981 filed Nov. 26, 2018 (now U.S. Pat. No. 10,333,503). The entirety of each of the aforementioned applications is hereby incorporated herein by reference in its entirety.

### TECHNICAL FIELD

Aspects of the present application relate to quantum computer control systems. More specifically, to methods and systems for a quantum controller with dynamic pulse routing.

### BACKGROUND

Limitations and disadvantages of conventional approaches to quantum computer control systems will become apparent to one of skill in the art, through comparison of such approaches with some aspects of the present method and system set forth in the remainder of this disclosure with reference to the drawings.

### BRIEF SUMMARY

Methods and systems are provided for a quantum controller with modular and dynamic pulse generation and routing, substantially as illustrated by and/or described in connection with at least one of the figures, as set forth more completely in the claims.

### BRIEF DESCRIPTION OF THE DRAWINGS

FIGS. 1A and 1B compare some aspects of classical (binary) computing and quantum computing.

FIG. 2 shows an example quantum computing system.

FIG. 3A shows an example quantum controller architecture in accordance with various example implementations of this disclosure.

FIG. 3B shows an example implementation of the quantum controller circuitry of FIG. 3A.

FIG. 4 shows an example implementation of the pulser of FIG. 3B.

FIG. 5 shows an example implementation of the pulse operations manager and pulse operations circuitry of FIG. 3B

FIG. 6 is a flowchart illustrating an example operation of a quantum controller in accordance with an example implementation of this disclosure.

### DETAILED DESCRIPTION

Classical computers operate by storing information in the form of binary digits (“bits”) and processing those bits via binary logic gates. At any given time, each bit takes on only one of two discrete values: 0 (or “off”) and 1 (or “on”). The logical operations performed by the binary logic gates are defined by Boolean algebra and circuit behavior is governed by classical physics. In a modern classical system, the circuits for storing the bits and realizing the logical operations are usually made from electrical wires that can carry two different voltages, representing the 0 and 1 of the bit, and transistor-based logic gates that perform the Boolean logic operations.

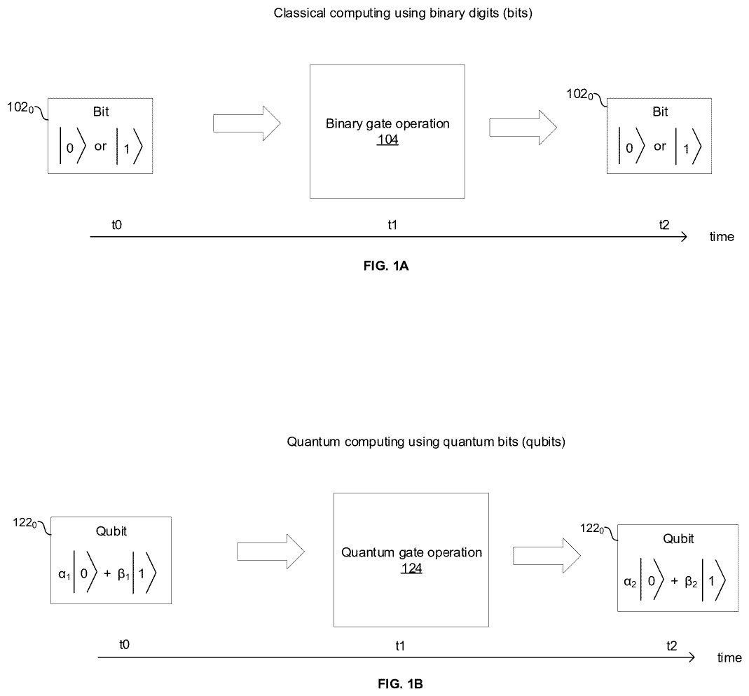

Shown in FIG. 1A is a simple example of a classical computer configured to a bit 102 and apply a single logic operation 104 to the bit 102. At time to the bit 102 is in a first state, at time t1 the logic operation 104 is applied to the bit 102, and at time t2 the bit 102 is in a second state determined by the state at time to and the logic operation. So, for example, the bit 102 may typically be stored as a voltage (e.g., 1 Vdc for a “1” or 0 Vdc for a “0”) which is applied to an input of the logic operation 104 (comprised of one or more transistors). The output of the logic gate is then either 1Vdc or 0Vdc, depending on the logic operation performed.

Obviously, a classical computer with a single bit and single logic gate is of limited use, which is why modern classical computers with even modest computation power contain billions of bits and transistors. That is to say, classical computers that can solve increasingly complex problems inevitably require increasingly large numbers of bits and transistors and/or increasingly long amounts of time for carrying out the algorithms. There are, however, some problems which would require an infeasibly large number of transistors and/or infeasibly long amount of time to arrive at a solution. Such problems are referred to as intractable.

Quantum computers operate by storing information in the form of quantum bits (“qubits”) and processing those qubits via quantum gates. Unlike a bit which can only be in one state (either 0 or 1) at any given time, a qubit can be in a superposition of the two states at the same time. More precisely, a quantum bit is a system whose state lives in a two dimensional Hilbert space and is therefore described as a linear combination α|0>+β|1>, where |0> and |1> are two basis states, and α and β are complex numbers, usually called probability amplitudes, which satisfy |α|²+|β|²=1. Using this notation, when the qubit is measured, it will be 0 with probability |α|² and will be 1 with probability |β|². |0 [symbol] and |1 [symbol] can also be represented by two-dimensional basis vectors

$$[ \begin{matrix}1 \\ 0\end{matrix} ] and [ \begin{matrix}0 \\ 1\end{matrix} ] ,$$

respectively, and then the qubit state is represented by

$$[ \begin{matrix}α \\ β\end{matrix} ] .$$

The operations performed by the quantum gates are defined by linear algebra over Hilbert space and circuit behavior is governed by quantum physics. This extra richness in the mathematical behavior of qubits and the operations on them, enables quantum computers to solve some problems much faster than classical computers (in fact some problems that are intractable for classical computers may become trivial for quantum computers).

Shown in FIG. 1B is a simple example of a quantum computer configured to store a qubit 122 and apply a single quantum gate operation 124 to the qubit 122. At time to the qubit 122 is described by α₁|0 [symbol] +β₁|1 [symbol] , at time t1 the logic operation 104 is applied to the qubit 122, and at time t2 the qubits 122 is described by α₂|0 [symbol] +β₂|1 [symbol] .

Unlike a classical bit, a qubit cannot be stored as a single voltage value on a wire. Instead, a qubit is physically realized using a two-level quantum mechanical system. Many physical implementations of qubits have been proposed and developed over the years with some being more promising than others. Some examples of leading qubits implementations include superconducting circuits, spin qubits, and trapped ions.

It is the job of the quantum controller to generate the precise series of external signals, usually pulses of electromagnetic waves and pulses of base band voltage, to perform the desired logic operations (and thus carry out the desired quantum algorithm). Example implementations of a quantum controller are described in further detail below.

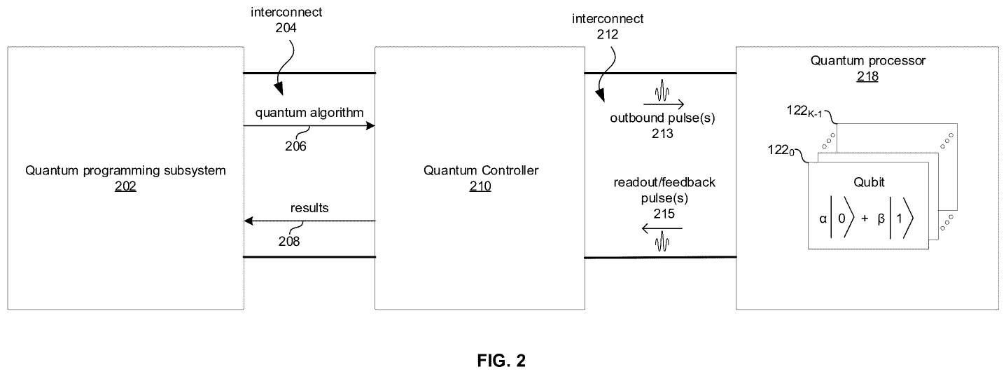

FIG. 2 shows an example quantum computing system. The system comprises a quantum programming subsystem 202, a quantum controller 210, and a quantum processor 218.

The quantum programming subsystem 202 comprises circuitry operable to generate a quantum algorithm description 206 which the quantum controller 210 can execute to carry out the quantum algorithm on the quantum processor 218 (i.e., generate the necessary outbound quantum pulse(s) 213) with little or no human intervention during runtime of the algorithm. In an example implementation, the quantum programming system 202 is a personal computer having installed on it a quantum controller software development kit (SDK) that enables a user to generate the quantum algorithm description 206 using a programming language. In an example implementation, the programming language may be a low-level language which has little or no abstraction from the instruction set used by the specific hardware of the quantum controller 210. Such instructions may be converted to machine code of the quantum controller 210 without need of a compiler or interpreter. In an example implementation, the programming language may be a high-level language which is much more abstracted from the particular hardware of the quantum controller 210. Such instructions may be compiled into machine code before they can be run on the quantum controller 210. In an example implementation the description 206 may be a machine code description of the quantum algorithm. In an example implementation, the description 206 may be a high-level description which the quantum controller 210 may itself compile into machine code. In an example implementation, the description 206 may be a high-level description which the quantum controller 210 may interpret into machine code during runtime. In an example implementation, an operating system or other software layer may run on the quantum controller 210 and the quantum algorithm description 206 may be software instructions that make use of an application programming interface (API) of the software running on the quantum controller 210.

The quantum programming subsystem 202 is coupled to the quantum controller 210 via interconnect 204 which may, for example, utilize universal serial bus (USB), peripheral component interconnect (PCIe) bus, wired or wireless Ethernet, or any other suitable communication protocol.

The quantum controller 210 comprises circuitry operable to load the quantum algorithm description 206 and then perform the quantum algorithm as per the quantum algorithm description 206. In an example implementation, quantum algorithm description 206 is machine code (i.e., series of binary vectors that represent instructions that the quantum controller's hardware can interpret and execute directly) which is loaded into the quantum controller 210. Then, execution of the machine code by the quantum controller 210 causes the quantum controller 210 to generate the necessary outbound pulse(s) 213 that correspond to the desired operations to be performed on the quantum processor 218 (e.g., sent to qubit(s) for manipulating a state of the qubit(s) or to readout resonator(s) for reading the state of the qubit(s), etc.). Depending on the quantum algorithm to be performed, outbound pulse(s) 213 for carrying out the algorithm may be predetermined at design time and/or may need to be determined during runtime. The runtime determination of the pulses may comprise performance of classical calculations and processing in the quantum controller 210 and/or the quantum programing subsystem 202 during runtime of the algorithm (e.g., runtime analysis of inbound pulses 215 received from the quantum processor 218).

Upon completion of a quantum algorithm and/or during a runtime of a quantum algorithm by the quantum controller 210, the quantum controller 210 may output data/results 298 to the quantum programming subsystem 202. In an example implementation these results may be used to generate a new quantum algorithm description 206 for a subsequent run of the quantum algorithm and/or update the quantum algorithm description during runtime.

The quantum controller 210 is coupled to the quantum processor 218 via interconnect 212 which may comprise, for example, one or more conductors and/or optical fibers.

The quantum processor 218 comprises K (an integer) quantum elements 122, which includes qubits (which could be of any type such as superconducting, spin qubits, ion trapped, etc.), and, where applicable, any other element(s) for processing quantum information, storing quantum information (e.g. storage resonator), and/or coupling the outbound quantum pulses 213 and 215 between interconnect 212 and the quantum element(s) 122 (e.g., readout resonator(s)). In an example implementation in which the quantum processor comprises readout resonators (or other readout circuitry) K may be equal the total number of qubits plus the number of readout circuits. That is, if each of Q (an integer) qubits of the quantum processor 218 is associated with a dedicated readout circuit, then K may be equal to 2Q. For ease of description, the remainder of this disclosure will assume such an implementation, but it need not be the case in all implementations. Other elements of the quantum processor 218 may include, for example, flux lines (electronic lines for carrying current), gate electrodes (electrodes for voltage gating), current/voltage lines, amplifiers, classical logic circuits residing on-chip in the quantum processor 218, and/or the like

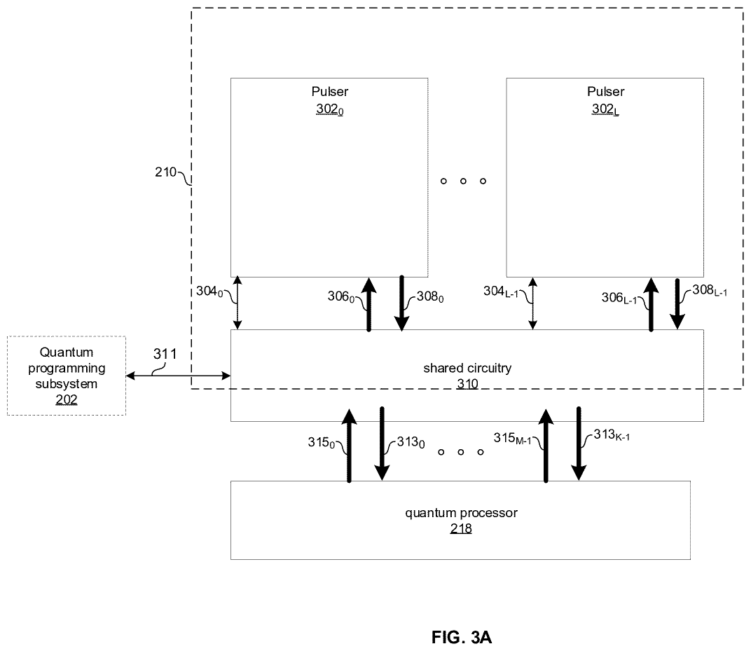

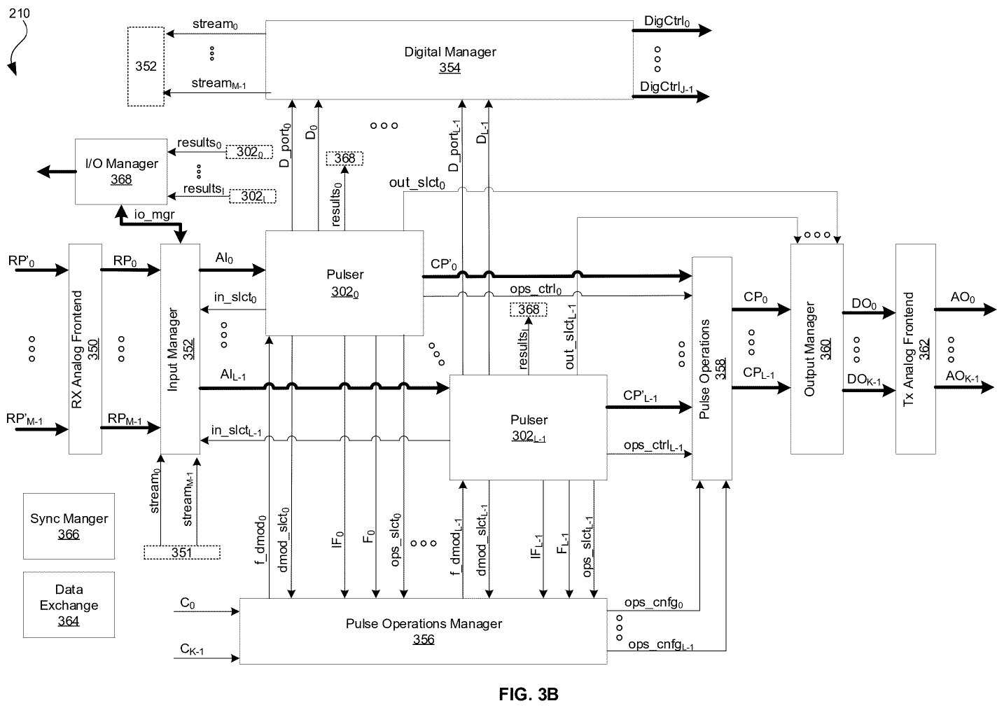

FIG. 3A shows an example quantum controller architecture in accordance with various example implementations of this disclosure. The quantum controller 210 comprises L (an integer ≥1) pulser circuits 302₀-302_{L-1} and shared circuitry 310.

In the example implementation shown, each pulser circuit 302_{I} (I an integer between 0 and L−1) comprises circuitry for exchanging information over signal paths 304_{I}, 306_{I}, and 308_{I}, where the signal path 308_{I} carries outbound pulses (e.g., 213 of FIG. 2) generated by the pulser circuit 302_{I} (which may be control pulses sent to the quantum processor 128 to manipulate a state of one or more qubits and/or readout pulses to readout a state of one or more qubits), the signal path 306_{I} carries inbound quantum element readout pulses (e.g., 215 of FIG. 2) to be processed by the pulser circuit 302₁, and signal path 304_{I} carries control information. Each signal path may comprise one or more conductors, optical channels, and/or wireless channels.

Each pulser circuit 302_{I} comprises circuitry operable to generate outbound pulses on signal path 308_{I} according to quantum control operations to be performed on the quantum processor 218. This involves very precisely controlling characteristics such as phase, frequency, amplitude, and timing of the outbound pulses. The characteristics of an outbound pulse generated at any particular time may be determined, at least in part, on inbound pulses received from the quantum processor 218 (via shared circuitry 310 and signal path 306_{I}) at a prior time. In an example implementation, the time required to close the feedback loop (i.e., time from receiving a first pulse on one or more of paths 315_{I}-315_{L} (e.g., at an analog to digital converter of the path) to sending a second pulse on one or more of paths 313₀-313_{L-1} (e.g., at an output of a digital-to-analog converter of the path), where the second pulse is based on the first pulse) is significantly less than the coherence time of the qubits of the quantum processor 218. For example, the time to close the feedback loop may be on the order of 100 nanoseconds. It should be noted that each signal path in FIG. 3A may in practice be a pair of signal paths for supporting generation of phase-quadrature (“I” and “Q”) pulse pairs.

In the example implementation shown, the shared circuitry 310 comprises circuitry for exchanging information with the pulser circuits 302₀-302_{L-1} over signal paths 304₀-304_{L-1}, 306₀-306_{L-1}, and 308₀-308_{L-1}, where each signal path 308_{I} carries outbound pulses generated by the pulser circuit 302_{I}, each signal path 306_{I} carries inbound pulses to be processed by pulser circuit 302_{I}, and each signal path 304_{I} carries control information such as flag/status signals, data read from memory, data to be stored in memory, data streamed to/from the quantum programming subsystem 202, and data to be exchanged between two or more pulsers 302₀-302_{L}. Similarly, in the example shown the shared circuitry 310 comprises circuitry for exchanging information with the quantum processor 218 over signal paths 315₀-315_{M-1} and 313₁-313_{K-1}, where each signal path 315ₘ (m an integer between 0 and M−1) carries inbound pulses from the quantum processor 218, and each signal path 313ₖ (k an integer between 0 and K−1) carries outbound pulses to the quantum processor 218. Additionally, in the example shown the shared circuitry 310 comprises circuitry for exchanging information with the quantum programming subsystem over signal path 311. The shared circuitry 310 may be: integrated with the quantum controller (e.g., on the same field programmable gate array or application specific integrated circuitry or printed circuit board); external to the quantum controller (e.g., on a separate FPGA, ASIC, or PCB connected to the quantum controller via one or more cables, backplanes, in other devices connected to the quantum processor 218, etc.); or partially integrated with the quantum controller and partially external to the quantum controller.

In various implementations, M may be less than, equal to, or greater than L, K may be less than, equal to, or greater than L, and M may be less than, equal to, or greater than K. For example, the nature of some quantum algorithms is such that not all K quantum elements need to be driven at the same time. For such algorithms, L may be less than K and one or more of the L pulsers 302_{I} may be shared among multiple of the K quantum elements circuits. That is, any pulser 302 may generate pulses for different quantum elements at different times. This ability of a pulser 302_{I} to generate pulses for different quantum elements at different times can reduce the required number of pulsers 302₀-302_{L-1} (i.e., reduce L) required to support a given number of quantum elements (thus saving significant resources, cost, size, overhead when scaling to larger numbers of qubits, etc.).

The ability of a pulser 302_{I} to generate pulses for different quantum elements at different times also enables reduced latency. As just one example, assume a quantum algorithm which needs to send a pulse to quantum element 122₀ at time T1, but whether the pulse is to be of a first type or second type (e.g., either an X pulse or a Hadamard pulse) cannot be determined until after processing an inbound readout pulse at time T1-DT (i.e., DT time intervals before the pulse is to be output). If there were a fixed assignment of pulsers 302₀-302_{L-1} to quantum elements of the quantum processor 218 (i.e., if 302₀ could only send pulses to quantum element 122₀, and 302₁ could only send pulses to quantum element 122₁, and so on), then pulser 302₀ might not be able to start generating the pulse until it determined what the type was to be. In the depicted example implementation, on the other hand, pulser 302₀ can start generating the first type pulse and pulser 302₁ can start generating the second type pulse and then either of the two pulses can be released as soon as the necessary type is determined. Thus, if the time to generate the pulse is That, in this example the example quantum controller 210 may reduce latency of outputting the pulse by Tₗₐₜ.

The shared circuitry 310 is thus operable to receive pulses via any one or more of the signals paths 308₀-308_{L-1} and/or 315₀-315_{M-1}, process the received pulses as necessary for carrying out a quantum algorithm, and then output the resulting processed pulses via any one or more of the signal paths 306₀-306_{L-1} and/or 313₀-313_{K-1}. The processing of the pulses may take place in the digital domain and/or the analog domain. The processing may comprise, for example: frequency translation/modulation, phase translation/modulation, frequency and/or time division multiplexing, time and/or frequency division demultiplexing, amplification, attenuation, filtering in the frequency domain and/or time domain, time-to-frequency-domain or frequency-to-time-domain conversion, upsampling, downsampling, and/or any other signal processing operation. At any given time, the decision as to from which signal path(s) to receive one or more pulse(s), and the decision as to onto which signal path(s) to output the pulse(s) may be: predetermined (at least in part) in the quantum algorithm description; and/or dynamically determined (at least in part) during runtime of the quantum algorithm based on classical programs/computations performed during runtime, which may involve processing of inbound pulses. As an example of predetermined pulse generation and routing, a quantum algorithm description may simply specify that a particular pulse with predetermined characteristics is to be sent to signal path 313₁ at a predetermined time. As an example of dynamic pulse determination and routing, a quantum algorithm description may specify that a readout pulse at time T-DT should be analyzed and its characteristics (e.g., phase, frequency, and/or amplitude) used to determine whether at time T pulser 302_{I} should output a pulse to a first quantum element or to a second quantum element. In various implementations of the quantum controller 210, the shared circuitry 310 may perform various other functions instead of and/or in addition to those described above. In general, the shared circuitry 310 may perform functions that are desired to be performed outside of the individual pulser circuits 302₀-302_{L-1}. For example, a function may be desirable to implement in the shared circuitry 310 where the same function is needed by a number of pulser circuits from 302₀-302₁₋₁ and thus may be shared among these pulser circuits instead of redundantly being implemented inside each pulser circuit. As another example, a function may be desirable to implement in the shared circuitry 310 where the function is not needed by all pulser circuits 302₀-302_{L-1} at the same time and/or on the same frequency and thus fewer than L circuits for implementing the function may be shared among the L pulser circuits 302₀-302_{L-1} through time and/or frequency division multiplexing. As another example, a function may be desirable to implement in the shared circuitry 310 where the function involves making decisions based on inputs, outputs, and/or state of multiple of the L pulser circuits 302₀-302_{L-1}, or other circuits. Utilizing a centralized coordinator/decision maker in the shared circuitry 310 may have the benefit(s) of: (1) reducing pinout and complexity of the pulser circuits 302₀-302_{L-1}; and/or (2) reducing decision-making latency. Nevertheless, in some implementations, decisions affecting multiple pulser circuits 302₀-302_{L-1} may be made by one or more of the pulser circuits 302₀-302_{L-1} where the information necessary for making the decision can be communicated among pulser circuits within a suitable time frame (e.g., still allowing the feedback loop to be closed within the qubit coherence time) over a tolerable number of pins/traces.

FIG. 3B shows an example implementation of the quantum controller of FIG. 2. The example quantum controller shown comprises pulsers 302₁-302_{L-1}, receive analog frontend 350, input manager 352, digital manager 354, pulse operations manager 356, pulse operations 358, output manager 360, transmit analog frontend 362, data exchange 364, synchronization manager 366, and input/output manager 368. Circuitry depicted in FIG. 3B other than pulser circuits 302₀-302_{L-1} corresponds to an example implementation of the shared circuitry 310 of FIG. 3A.

The receive analog frontend 350 comprises circuitry operable to concurrently process up to M (an integer ≥1) analog inbound signals (RP′₀-RP′_{M-1}) received via signal paths 315₀-315_{M-1} to generate up to M concurrent inbound signals (RP₀-RP_{M-1}) to be output to input manager 352 via one or more signal paths. Although there is shown to be M signals RP and M signals RP′, this need not be the case. Such processing may comprise, for example, analog-to-digital conversion, filtering, upconversion, downconversion, amplification, attenuation, time division multiplexing/demultiplexing, frequency division multiplexing/demultiplexing, and/or the like. In various implementations, M may be less than, equal to, or greater than L and M may be less than, equal to, or greater than K.

The input manager 352 comprises circuitry operable to route any one or more of signals (RP₀-RP_{M-1}) to any one or more of pulsers 302₀-302_{L-1} (as signal(s) AI₀-AI_{L-1}) and/or to other circuits (e.g. as signal io_mgr to I/O manager 368). In an example implementation, the input manager 352 comprises one or more switch networks, multiplexers, and/or the like for dynamically reconfiguring which signals RP₀-RP_{M-1} are routed to which pulsers 302₀-302_{L-1}. This may enable time division multiplexing multiple of the signals RP₀-RP_{M-1} onto a single signal AI_{I} and/or time division demultiplexing components (e.g., time slices) of a signal RPₘ onto multiple of the signals AI₀-AI_{L-1}. In an example implementation, the input manager 352 comprises one or more mixers and/or filters for frequency division multiplexing multiple of the signals RP₀-RP_{M-1} onto a single signal AI_{I} and/or frequency division demultiplexing components (e.g., frequency bands) of a signal RPₘ onto multiple of the signals AI₀-AI_{L-1}. The signal routing and multiplexing/demultiplexing functions performed by the input manager 352 enables: a particular pulser 302_{I} to process different inbound pulses from different quantum elements at different times; a particular pulser 302_{I} to process different inbound pulses from different quantum elements at the same time; and multiple of the pulsers 302₀-302_{L-1} to processes the same inbound pulse at the same time. In the example implementation shown, routing of the signals RP₀-RP_{M-1} among the inputs of the pulsers 302₀-302_{L-1} is controlled by digital control signals in_slot₀-in_slot_{L-1} from the pulsers 302₀-302_{L-1}. In another implementation, the input manager may be operable to autonomously determine the appropriate routing (e.g., where the quantum algorithm description includes instructions to be loaded into memory of, and executed by, the input manager 352). In the example implementation, the input manager 352 is operable to rout input signals RP₀-RP_{M-1} to the I/O manager 368 (as signal(s) io_mgr), to be sent to the quantum programing subsystem 202. This routing may, for example, be controlled by signals from the digital manager 352. In an example implementation, for each input signal RPₘ there is a digital signal, streamₘ, from the digital manager 354 to the input manager 352 that controls whether RPₘ will be sent from the input manager 352 to the I/O manager 368 and from there to the quantum programing subsystem 202.

Each of the pulsers 302₀-302_{L-1} is as described above with reference to FIG. 3A. In the example implementation shown, each pulsers 302_{I} is operable to generate raw outbound pulses CP′, (“raw” is used simply to denote that the pulse has not yet been processed by pulse operations circuitry 358) and digital control signals in_slctᵢ, D_portᵢ, D_{I}, out_slct_{I}, ops_ctrl_{I}, ops_slct_{I}, IF_{I}, F_{I}, and dmod_sct_{I}, for carrying out quantum algorithms on the quantum processor 218, and results_{I} for carrying intermediate and/or final results generated by the pulser 302_{I} to the quantum programming subsystem 202. One or more of the pulsers 302₀-302_{L-1} may receive and/or generate additional signals which are not shown in FIG. 3A for clarity of illustration. The raw outbound pulses CP′₀-CP′_{L-1} are conveyed via signal paths 308₀-308_{L-1} and the digital control signals are conveyed via signal paths 304₀-304_{L-1}. Each of the pulsers 302_{I} is operable to receive inbound pulse signal AI_{I} and signal f_dmod_{I}. Pulser 302_{I}, may process the inbound signal AI_{I} to determine the state of certain quantum element(s) in the quantum processor 218 and use this state information for making decisions such as, for example, which raw outbound pulse CP′_{I} to generate next, when to generate it and what control signals to generate to affect the characteristics of that raw outbound pulse appropriately. Pulser 302_{I} may use the signal f_dmod_{I} for determining how to process inbound pulse signal AI_{I}. As an example, when Pulse generator 302₁ needs to process an inbound signal AI₁ from quantum element 122₃, it can send a dmod_sclt₁ signal that directs pulse operations manager 356 to send, on f_dmod₁, settings to be used for demodulation of an inbound signal AI₁ from quantum element 122₃ (e.g., the pulse operations manager 356 may send the value cos (ω₃*time_stamp+ϕ₃), where ω₃ is the frequency of quantum element 122₃, time_stamp is amount of time passed since the reference point, for instance the time at which quantum algorithm started running, and ϕ₃ is the phase of the total frame rotation of quantum element 122₃, i.e. the accumulated phase of all frame rotations since the reference point).

The pulse operations circuitry 358 is operable to process the raw outbound pulses CP′₀-CP′_{L-1} to generate corresponding output outbound pulses CP₀-CP_{L-1}. This may comprise, for example, manipulating the amplitude, phase, and/or frequency of the raw pulse CP′_{I}. The pulse operations circuitry 358 receives raw outbound pulses CP′₀-CP′_{L-1} from pulsers 302₀-302_{L-1}, control signals ops_cnfg₀-ops_cnfg_{L-1} from pulse operations manager 356, and ops_ctrl₀-ops_ctrl_{L-1} from pulsers 302₀-302_{L-1}.

The control signal ops_cnfg_{I} configures, at least in part, the pulse operations circuitry 358 such that each raw outbound pulse CP′, that passes through the pulse operations circuitry 358 has performed on it one or more operation(s) tailored for that particular pulse. To illustrate, denoting a raw outbound pulse from pulser 3023 at time T1 as CP′_{3,T1}, then, at time T1 (or sometime before T1 to allow for latency, circuit setup, etc.), the digital control signal ops_cnfg₃ (denoted ops_cnfg_{3,T1} for purposes of this example) provides the information (e.g., in the form of one or more matrix, as described below) as to what specific operations are to be performed on pulse CP′_{3,T1}. Similarly, ops_cnfg_{4,T1} provides the information as to what specific operations are to be performed on pulse CP′_{4,T1}, and ops_cnfg_{3,T2} provides the information as to what specific operations are to be performed on pulse CP′_{4,T1}.

The control signal ops_ctrl_{I} provides another way for the pulser 302_{I} to configure how any particular pulse is processed in the pulse operations circuitry 358. This may enable the pulser 302_{I} to, for example, provide information to the pulse operation circuitry 358 that does not need to pass through the pulse operation manager 356. For example, the pulser 302_{I} may send matrix values calculated in real-time by the pulser 302_{I} to be used by the pulse operation circuitry 358 to modify pulse CP′_{I}. These matrix values arrive to the pulse operation circuitry 358 directly from the pulser 302_{I} and do not need to be sent to the pulse operation manager first. Another example maybe that the pulser 302_{I} provides information to the pulse operation circuitry 358 to affect the operations themselves (e.g. the signal ops_ctrl_{I} can choose among several different mathematical operations that can be performed on the pulse).

The pulse operations manager 356 comprises circuitry operable to configure the pulse operations circuitry 358 such that the pulse operations applied to each raw outbound pulse CP′, are tailored to that particular raw outbound pulse. To illustrate, denoting a first raw outbound pulse to be output during a first time interval T1 as CP′_{I,T1}, and a second raw outbound pulse to be output during a second time interval T2 as CP′_{I,T2}, then pulse operations circuitry 358 is operable to perform a first one or more operations on CP′_{I,T1} and a second one or more operations on CP′_{1,T2}. The first one or more operations may be determined, at least in part, based on to which quantum element the pulse CP_{1,T1} is to be sent, and the second one or more operations may be determined, at least in part, based on to which quantum element the pulse CP_{1,T2} is to be sent. The determination of the first one or more operations and second one or more operations may be determined dynamically during runtime.

The transmit analog frontend 362 comprises circuitry operable to concurrently process up to K digital signals DOK to generate up to K concurrent analog signals AOₖ to be output to the quantum processor 218. Such processing may comprise, for example, digital-to-analog conversion, filtering, upconversion, downconversion, amplification, attenuation, time division multiplexing/demultiplexing, frequency division multiplexing/demultiplexing and/or the like. In an example implementation, each of the one or more of signal paths 313₀-313_{K-1} (FIG. 3A) represents a respective portion of Tx analog frontend circuit 362 as well as a respective portion of interconnect 212 (FIG. 2) between the Tx analog frontend circuit 362 and the quantum processor 218. Although there is one-to-one correspondence between the number of DO signals and the number of AO signals in the example implementation described here, such does not need to be the case. In another example implementation, the analog frontend 362 is operable to map more (or fewer) signals DO to fewer (or more) signals AO.

The output manager 360 comprises circuitry operable to route any one or more of signals CP₀-CP_{L-1} to any one or more of signal paths 313₀-313_{K-1}. As just one possible example, signal path 313₀ may comprise a first path through the analog frontend 362 (e.g., a first mixer and DAC) that outputs AO₀ and traces/wires of interconnect 212 that carry signal AO₀; signal path 313₁ may comprise a second path through the analog frontend 362 (e.g., a second mixer and DAC) that outputs AO₁ and traces/wires of interconnect 212 that carry signal AO₁, and so on. In an example implementation, the output manager 360 comprises one or more switch networks, multiplexers, and/or the like for dynamically reconfiguring which one or more signals CP₀-CP_{L-1} are routed to which signal paths 313₀-313_{K-1}. This may enable time division multiplexing multiple of the signals CP₀-CP_{L-1} onto a single signal path 313k and/or time division demultiplexing components (e.g., time slices) of a signal CPₘ onto multiple of the signal paths 313₀-313_{K-1}. In an example implementation, the output manager 360 comprises one or more mixers and/or filters for frequency division multiplexing multiple of the signals CP₀-CP_{M-1} onto a single signal path 313k and/or frequency division demultiplexing components (e.g., frequency bands) of a signal CPₘ onto multiple of the signal paths 313₀-313_{K-1}. The signal routing and multiplexing/demultiplexing functions performed by the output manager 360 enables: routing outbound pulses from a particular pulser 302_{I} to different ones of the signal paths 313₀-313_{K-1} at different times; routing outbound pulses from a particular pulser 302_{I} to multiple of the signal paths 313₀-313_{K-1} at the same time; and multiple of the pulsers 302₀-302_{L-1} generating pulses for the same signal path 313k at the same time. In the example implementation shown, routing of the signals CP₀-CP_{L-1} among the signal paths 313₀-313_{K-1} is controlled by digital control signals out_slct₀-out_slct_{L-1} from the pulsers 302₀-302_{L-1}. In another implementation, the output manager 360 may be operable to autonomously determine the appropriate routing (e.g., where the quantum algorithm description includes instructions to be loaded into memory of, and executed by, the output manager 362).

The digital manager 354 comprises circuitry operable to process and/or route digital control signals (DigCtrl₀-DigCtrl_{J-1}) to various circuits of the quantum controller 210 and/or external circuits coupled to the quantum controller 210. In the example implementation shown, the digital manager receives, from each pulser 302₁, (e.g., via one or more of signal paths 304₀-304_{N-1}) a digital signal D_{I} that is to be processed and routed by the digital manager 354, and a control signal D_port_{I} that indicates to which output port(s) of the digital manager 354 the signal D_{I} should be routed. The digital control signals may be routed to, for example, any one or more of circuits shown in FIG. 3B, switches/gates which connect and disconnect the outputs AO₀-AO_{K-1} from the quantum processor 218, external circuits coupled to the quantum controller 210 such as microwave mixers and amplifiers, and/or any other circuitry which can benefit from on real-time information from the pulser circuits 302₀-302_{L-1}. Each such destination of the digital signals may require different operations to be performed on the digital signal (such as delay, broadening, or digital convolution with a given digital pattern). These operations may be performed by the digital manager 354 and may be specified by control signals from the pulsers 302₀-302_{L-1}. This allows each pulser 302_{I} to generate digital signals to different destinations and allows different ones of pulse generators 302₀-302_{L-1} to generate digital signals to the same destination while saving resources.

The synchronization manager 366 comprises circuitry operable to manage synchronization of the various circuits shown in FIG. 3B. Such synchronization is advantageous in a modular and dynamic system, such as quantum controller 210, where different ones of pulsers 302₀-302_{L-1} generate, receive, and process pulses to and from different quantum elements at different times. For example, while carrying out a quantum algorithm, a first pulser circuit 302₁ and a second pulser circuit 302₂ may sometimes need to transmit pulses at precisely the same time and at other times transmit pulses independently of one another. In the example implementation shown, the synchronization manager 366 reduces the overhead involved in performing such synchronization.

The data exchange circuitry 364 is operable to manage exchange of data among the various circuits shown in FIG. 3B. For example, while carrying out a quantum algorithm, first pulser circuit 302₁ and a second pulser circuit 302₂ may sometimes need to exchange information. As just one example, pulser 302₁ may need to share, with pulser 302₂, the characteristics of an inbound signal AI₁ that it just processed so that pulser 302₂ can generate a raw outbound pulse CP′₂ based on the characteristics of AI₁. The data exchange circuitry 364 may enable such information exchange. In an example implementation, the data exchange circuitry 364 may comprise one or more registers to and from which the pulsers 302₀-302_{L-1} can read and write.

The I/O manager 368 is operable to route information between the quantum controller 210 and the quantum programming subsystem 202.

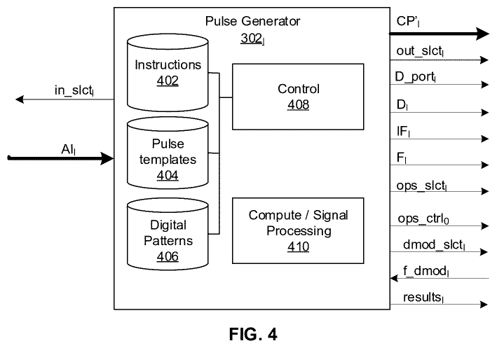

FIG. 4 shows an example implementation of the raw pulser of FIG. 3B. The example pulser 302_{I} shown comprises instruction memory 402, pulse template memory 404, digital pattern memory 406, control circuitry 408, and compute and/or signal processing circuitry (CSP) 410.

The memories 402, 404, 406 may comprise one or more be any type of suitable storage elements (e.g., DRAM, SRAM, Flash, etc.). The instructions stored in memory 402 are instructions to be executed out by the pulser 302_{I} for carrying out its role in a quantum algorithm. Because different pulsers 302₀-302_{L-1} have different roles to play in any particular quantum algorithm (e.g., generating different pulses at different times), the instructions memory 402 for each pulser 302_{I} may be specific to that pulser. For example, the quantum algorithm description 206 from the quantum programming subsystem 202 may comprise a first set of instructions to be loaded (via I/O manager 368) into pulser 302₀, a second set of instructions to be loaded into pulser 302₁, and so on. Each pulse template stored in memory 404 comprises a sequence of one or more samples of any arbitrary shape (e.g., Gaussian, sinc, impulse, etc.) representing the pulses to be sent to pulse operation circuitry 358. Each digital pattern stored in memory 406 comprises a sequence of one or more binary values which may represent the digital pulses to be sent to the digital manager 354 for generating digital control signals DigCtrl₀-DigCtrl_{J-1}.

The control circuitry 408 is operable to execute the instructions stored in memory 402 to process inbound signal AI_{I}, generate raw outbound pulses CP′_{I}, and generate digital control signals in_slct_{I}, out_slct_{I}, D_port_{I}, D_{I}, IF_{I}, F_{I}, ops_slct_{I}, ops_ctrl_{I}, results_{I}, and dmod_slct_{I}. In the example implementation shown, the processing of the inbound signal AI_{I} is performed by the CSP circuitry 410 and based (at least in part) on the signal f_dmod_{I}.

The compute and/or signal processing circuitry (CSP) 410 is operable to perform computational and/or signal processing functions, which may comprise, for example Boolean-algebra based logic and arithmetic functions and demodulation (e.g., of inbound signals AI_{I}).

In operation of an example implementation, generation of a raw outbound pulse CP′_{I} comprises the control circuitry 408: (1) determining a pulse template to retrieve from memory 404 (e.g., based on a result of computations and/or signal processing performed by the CSP 410); (2) retrieving the pulse template; (3) performing some preliminary processing on the pulse template; (4) determining the values of F, IF, ops_slct_{I}, and dmod_slct_{I} to be sent to the pulse operation manager 356 (as predetermined in the quantum algorithm description and/or determined dynamically based on results of computations and/or signal processing performed by the CSP 410); (5) determining the value of ops_ctrl_{I} to be sent to the pulse operation circuitry 358; (6) determining the value of in_slct_{I} to be sent to the input manager 352; (7) determining a digital pattern to retrieve from memory 406 (as predetermined in the quantum algorithm description and/or determined dynamically based on results of computations and/or signal processing performed by the CSP 410); (8) outputting the digital pattern as D_{I} to the digital manager along with control signal D_port_{I} (as predetermined in the quantum algorithm description and/or determined dynamically based on results of computations and/or signal processing performed by the CSP 410); (9) outputting the raw outbound pulse CP′_{I} to the pulse operations circuitry 358; (10) outputting results_{I} to the I/O manager.

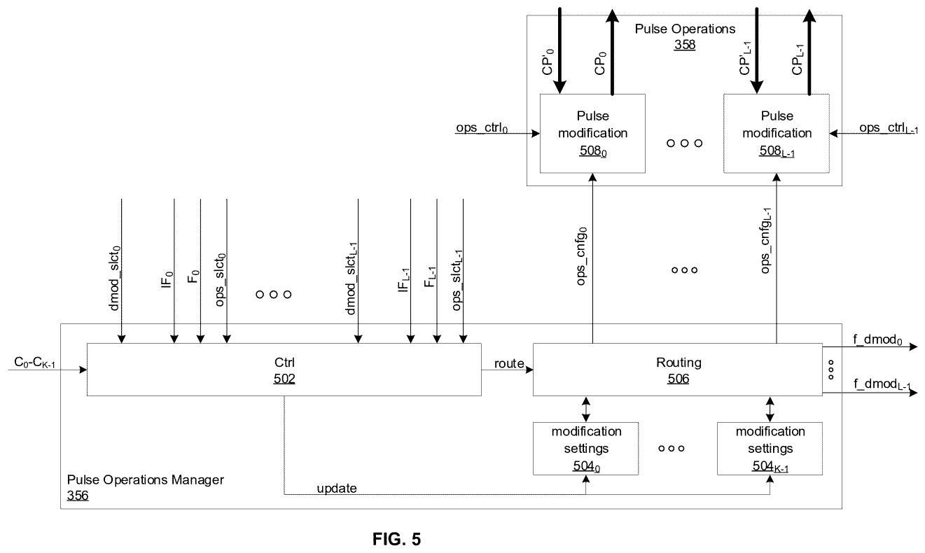

FIG. 5 shows an example implementation of the pulse operations manager and pulse operations circuitry of FIG. 3B. The pulse operations circuitry 358 comprises a plurality of pulse modification circuits 508₀-508_{L-1}. The pulse operations manager 356 comprises control circuitry 502, routing circuitry 506, and a plurality of modification settings circuits 504₀-504_{K-1}.

Although the example implementation has a 1-to-1 correspondence between pulse modification circuits 508₀-508_{L-1} and pulser circuits 302₀-302_{L-1} (i.e., there are L of each), that does not need to be the case. In other implementations there may be fewer pulse modification circuits 508 than pulser circuits 302. Similarly, other implementations may comprise more pulse modification circuits 508 than pulser circuits 302.

Each pulse modification circuit 508_{I} is operable to process raw outbound pulses CP′_{I} according to ops_cnfg_{I} and ops_ctrl_{I} to output outbound pulses CP_{I}. Such processing may comprise adjusting a phase, frequency, and/or amplitude of the raw outbound pulses CP_{I}. In an example implementation, ops_cnfg_{I} is in the form of elements of one or more matrices of complex numbers and the processing comprises multiplying a matrix representation of the raw outbound pulses CP_{I} with the matrix/matrices of ops_cnfg_{I}, as described below.

As an example, in some instances two of the pulsers 302₀-302_{L-1} may generate two raw outbound pulses which are a phase-quadrature pulse pair. For example, assuming CP′₁ and CP′₂ are a phase-quadrature pulse pair to be output on path 313₃. In this example, pulse operations circuitry 358 may process CP₁ and CP₂ by multiplying a vector representation of CP′₁ and CP′₂ by one or more 2 by 2 matrices to: (1) perform single-sideband-modulation, as given by

$$( \begin{matrix}{CP}_{1} \\ {CP}_{2}\end{matrix} ) = ( \begin{matrix}cos ( ω * time\_stamp ) & - sin ( ω * time\_stamp ) \\ sin ( ω * time\_stamp ) & cos ( ω * time\_stamp )\end{matrix} ) ( \begin{matrix}{CP}_{1}^{′} \\ {CP}_{2}^{′}\end{matrix} ) ,$$

where ω is the frequency of the single side band modulation and time_stamp is the time passed since the reference time (e.g. the beginning of a certain control protocol); (2) keep track of frame-of-reference rotations, as given by

$$( \begin{matrix}{CP}_{1} \\ {CP}_{2}\end{matrix} ) = ( \begin{matrix}cos ( ϕ ) & - sin ( ϕ ) \\ sin ( ϕ ) & cos ( ϕ )\end{matrix} ) ( \begin{matrix}{CP}_{1}^{′} \\ {CP}_{2}^{′}\end{matrix} ) ,$$

where ϕ is the total phase that the frame of reference accumulated since the reference time; and/or (3) perform an IQ-mixer correction

$$( \begin{matrix}{CP}_{1} \\ {CP}_{2}\end{matrix} ) = ( \begin{matrix}{C}_{00} & {C}_{01} \\ {C}_{10} & {C}_{11}\end{matrix} ) ( \begin{matrix}{CP}_{1}^{′} \\ {CP}_{2}^{′}\end{matrix} ) ,$$

where C₀₀, C₀₁, C₁₀, and C₁₁ are the elements of a matrix that corrects for IQ-mixer imperfections. In an example implementation, each modification settings circuit, 504ₖ, contains registers that contain the matrix elements of three matrices:

$${C}_{k} = ( \begin{matrix}{C}_{k 00} & {C}_{k 01} \\ {C}_{k 10} & {C}_{k 11}\end{matrix} ) ,$$

an IQ-mixer correction matrix;

$${S}_{k} = ( \begin{matrix}cos ( {ω}_{k} * time\_stamp ) & - sin ( {ω}_{k} * time\_stamp ) \\ sin ( {ω}_{k} * time\_stamp ) & cos ( {ω}_{k} * time\_stamp )\end{matrix} ) ,$$

a single side band frequency modulation matrix; and

$${F}_{k} = ( \begin{matrix}cos ( {ϕ}_{k} ) & - sin ( {ϕ}_{k} ) \\ sin ( {ϕ}_{k} ) & cos ( {ϕ}_{k} )\end{matrix} ) ,$$

a frame rotation matrix, which rotates the IQ axes around the axis perpendicular to the IQ plane (i.e. the z-axis if I and Q are the x-axis and y-axis). In an example implementation, each modification parameters circuit 504ₖ also contains registers that contain the elements of the matrix products C_{K}SₖFₖ and SₖFₖ.

The control circuitry 502 is operable to exchange information with the pulser circuits 302₀-302_{L-1} to generate values of ops_confg₀-ops_confg_{L-1} and f_demod₀-f_demod_{L-1} by controlling routing circuitry 506 based on signals ops_slct₀-ops_slct_{L-1} and dmod_slct₀-dmod_slct_{L-1}, and by updating pulse modification settings 504₀-504_{K-1} based on IF₀-IF_{L-1} and F₀-F_{L-1} such that pulse modification settings output to pulse operations circuitry 358 are specifically tailored to each raw outbound pulse (e.g., to which quantum element 222 the pulse is destined, to which signal path 313 the pulse is destined, etc.) to be processed by pulse operations circuitry 358.

Each modification settings circuit 504ₖ comprises circuitry operable to store modification settings for later retrieval and communication to the pulse operations circuitry 358. The modification settings stored in each modification settings circuit 504ₖ may be in the form of one or more two-dimensional complex-valued matrices. Each signal path 313₀-313_{K-1} may have particular characteristics (e.g., non-idealities of interconnect, mixers, switches, attenuators, amplifiers, and/or circuits along the paths) to be accounted for by the pulse modification operations. Similarly, each quantum element 122₀-122ₖ may have a particular characteristics (e.g. resonance frequency, frame of reference, etc.). In an example implementation, the number of pulse modification settings, K, stored in the circuits 504 corresponds to the number of quantum element 122₀-122_{K-1} and of signal paths 313₀-313_{K-1} such that each of the modification settings circuits 504₀-504_{K-1} stores modification settings for a respective one of the quantum elements 122₀-122_{K-1} and/or paths 313₀-313_{K-1}. In other implementations, there may be more or fewer pulse modification circuits 504 than signal paths 313 and more or fewer pulse modification circuits 504 than quantum elements 122 and more or fewer signal paths 313 than quantum elements 122.

The routing circuitry 506 is operable to route modification settings from the modification settings circuits 504₀-504_{L-1} to the pulse operations circuit 358 (as ops_confg₀-ops_confg_{L-1}) and to the pulsers 302₀-302_{L-1} (as f_dmod₀-f_dmod_{L-1}). In the example implementation shown, which of the modification settings circuits 504₀-504_{K-1} has its/their contents sent to which of the pulse modification circuits 508₀-508_{L-1} and to which of the pulsers 302₀-302_{L-1} is controlled by the signals “route” from the control circuitry 502.

The signal ops_slct_{I} informs the pulse operations manager 356 as to which modification parameters 504ₖ to send to the pulse modification circuit 508_{I}. The pulser 302_{I} may determine ops_slct_{I} based on the particular quantum element 122ₖ and/or signal path 313ₖ to which the pulse is to be transmitted (e.g., the resonant frequency of the quantum element, frame of reference, and/or mixer correction). The determination of which quantum element and/or signal path to which a particular pulser 302_{I} is to send an outbound pulse at a particular time may be predetermined in the quantum algorithm description or may be determined based on calculations performed by the pulser 302_{I} and/or others of the pulsers 302₀-302_{L-1} during runtime. The control circuitry 502 may then use this information to configure the routing block 506 such that the correct modification settings are routed to the correct one of the pulse modification circuits 508₀-508_{L-1}.

In an example implementation, each ops_cnfgₖ signal may comprise two components ops_cnfg_{k,0} and ops_cnfg_{k,1} and the pulse modification circuits 508₁ and 508₂ may perform the following operation: CP₁=ops_cnfg_{1,0}*CP′₁+ops_cng_{2,1}*CP′₂ and CP₂=ops_cnfg_{1,1}*CP′₁+ops_cnfg_{2,0}*CP′₂. To generate CP₁ and CP₂ as a phase-quadrature pulse pair, ops_slct₁ and ops_slct2 may instruct the pulse operations manager 256 to set ops_cnfg_{1,0}=CSFₖ₀₀, ops_cnfg_{1,1}=CSFₖ₁₀, ops_cnfg_{2,0}=CSFₖ₁₁, and ops_cnfg_{2,1}=CSFₖ₀₁ such that

$$( \begin{matrix}{CP}_{1} \\ {CP}_{2}\end{matrix} ) = ( \begin{matrix}{CSF}_{00} & {CSF}_{01} \\ {CSF}_{10} & {CSF}_{11}\end{matrix} ) ( \begin{matrix}{CP}_{1}^{′} \\ {CP}_{2}^{′}\end{matrix} ) ,$$

where CSFₖᵢⱼ is the ij^{th} matrix element of CSFₖ. To generate CP₁ as a single-phase pulse, ops_slct₁ may instruct the pulse operations manager 356 to set ops_cnfgs_{1,0}=SFₛ₀₀=cos(ωₖ*time_stamp+ϕₖ) and ops_cnfg_{2,1=0}, such that CP₁=cos(ωₖ*time_stamp+ϕₖ)CP′₁. Thus, such an implementation enables each pulse generator 302_{I} to generate pulses to be played as a part of phase-quadrature pulse pairs or as independent single-phase pulses and modify these pulses with any one of the CSF or SF matrices, which are shared among all pulse generators.

In an example implementation, the digital signal IF_{I} instructs the pulse operations manager 356 to update a frequency setting of the modification settings circuit 504ₖ indicated by ops_slct_{I}. In an example implementation, the frequency setting is the matrix Sₖ (described above) and the signal IF_{I} carries new values indicating the new ωₖ to be used in the elements of the matrix Sₖ. The new values may, for example, be determined during a calibration routine (e.g., performed as an initial portion of the quantum algorithm) in which one or more of the pulse generators 302₀-302_{L-1} sends a series of outbound pulses CP, each at a different carrier frequency, and then measures the corresponding inbound signals AI.

In an example implementation, the signal F_{I} instructs the pulse operations manager 356 to update a frame setting of the modification settings circuit 504ₖ indicated by ops_slct₁. In an example implementation, the frame setting is the matrix Fₖ (described above) and the signal F_{I} carries a rotation matrix F_{I} which multiplies with Fₖ to rotate Fₖ. This can be written as

$${F}_{k} = {F}_{1} {F}_{k} = ( \begin{matrix}cos ( Δϕ ) & - sin ( Δϕ ) \\ sin ( Δϕ ) & cos ( Δϕ )\end{matrix} ) ( \begin{matrix}cos ( {ϕ}_{k} ) & - sin ( {ϕ}_{k} ) \\ sin ( {ϕ}_{k} ) & cos ( {ϕ}_{k} )\end{matrix} ) = ( \begin{matrix}cos ( {ϕ}_{k} + Δ ϕ ) & - sin ( {ϕ}_{k} + Δ ϕ ) \\ sin ( {ϕ}_{k} + Δϕ ) & cos ( {ϕ}_{k} + Δϕ )\end{matrix} ) ,$$

where ϕₖ is the frame of reference before the rotation and Δϕ is the amount by which to rotate the frame of reference. The pulser 302 may determine Δϕ based on a predetermined algorithm or based on calculations performed by the pulse generator 302_{I} and/or others of the pulse generators 302₀-302_{L-1} during runtime.

In an example implementation, the signal dmod_sclt_{I} informs the pulse operations manager 356 from which of the modification settings circuits 504ₖ to retrieve values to be sent to pulser 302_{I} as f_dmod_{I}. The pulser 302_{I} may determine dmod_slct_{I}, based on the particular quantum element 122ₖ and/or signal path 315ₖ from which the pulse to be processed arrived. The determination of from which quantum element and/or signal path a particular pulser 302_{I} is to process an inbound pulse at a particular time may be predetermined in the quantum algorithm description or may be determined based on calculations performed by the pulser 302_{I} and/or others of the pulsers 302₀-302_{L-1} during runtime. The control circuitry 502 may then use this information to configure the routing block 506 such that the correct modification settings are routed to the correct one of the pulsers 302₀-302_{L-1}. For example, when pulse generation circuit 302_{I} needs to demodulate a pulse signal AI_{I} from quantum element 122ₖ, it will send a dmod_sclt_{I} signal instructing the pulse operation manager 356 to rout the element SFₖ₀₀=cos(ωₖ*time_stamp+ϕₖ) from modification settings circuit 504ₖ to pulser 302_{I} (as f_dmod_{I}).

In the example implementation shown, the digital signals C₀-C_{K-1} provide information about signal-path-specific modification settings to be used for each of the signal paths 313₀-313_{K-1}. For example, each signal Cₖ may comprise a matrix to be multiplied by a matrix representation of a raw outbound pulse CP′_{I}, such that the resulting output outbound pulse is pre-compensated for errors (e.g., resulting from imperfections in mixers, amplifiers, wiring, etc.) introduced as the outbound pulse propagates along signal path 313k. The result of the pre-compensation is that output outbound pulse CP_{I} will have the proper characteristics upon arriving at the quantum processor 218. The signals C₀-C_{K-1} may, for example, be calculated by the quantum controller 210 itself, by the programming subsystem 202, and/or by external calibration equipment and provided via I/O manager 368. The calculation of signals may be done as part of a calibration routine which may be performed before a quantum algorithm and/or may be determined/adapted in real-time as part of a quantum algorithm (e.g., to compensate for temperature changes during the quantum algorithm).

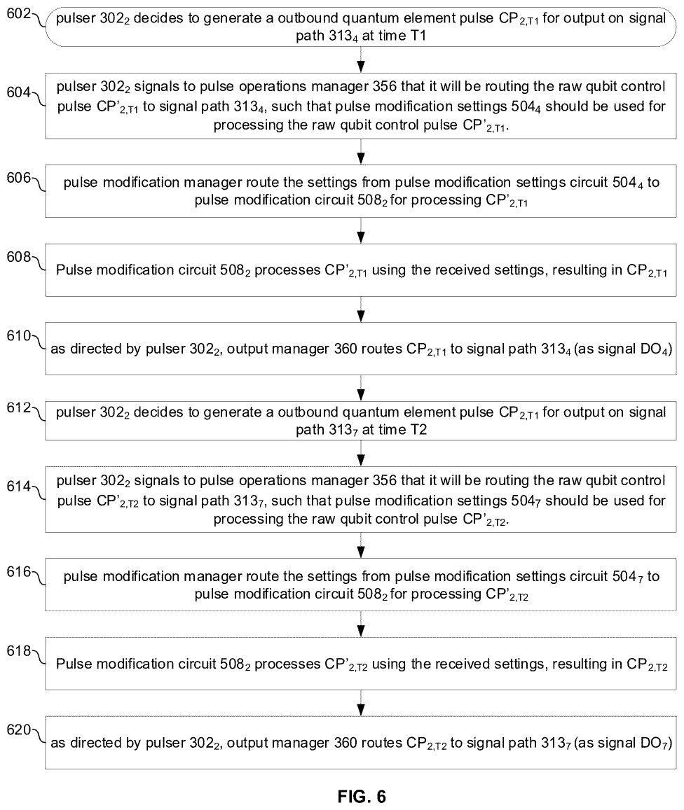

FIG. 6 is a flowchart illustrating an example operation of a quantum controller in accordance with an example implementation of this disclosure.

The process begins with block 602 in which pulser 302₂ decides to generate a raw outbound pulse CP′_{2,T1} to be output on signal path 313₄ at time T1. The decision is based on instructions loaded in memory 402 and may take into account the result of computations performed by the CSP 410 of the pulser 302₂ and/or CSP 410 of another of the pulsers 302₀-302_{L-1} (e.g., based on an inbound quantum element readout signal AI₂ demodulated by a CSP 410).

In block 604, pulser 302₂ signals to pulse operations manager 356, via signal ops_slct₂, that it wants the raw outbound pulse CP′_{2,T1} to be modified with pulse modification settings stored in 504₄.

In block 606, pulse modification manager 356 routes the settings from pulse modification settings circuit 504₄ to pulse modification circuit 508₂.

In block 608, pulse modification circuit 508₂ processes CP′_{2,T1} using the settings received in block 606. The result is output outbound quantum pulse CP_{2,T1}.

In block 610, as directed by pulser 302₂, output manager 360 routes CP_{2,T1} to signal path 313₄ (as signal DO₄).

In block 612, pulser 302₂ decides to generate a raw outbound pulse CP′_{2,T2} to be output on signal path 313₇ at time T2. The decision is based on instructions loaded in memory 402 and may take into account the result of computations performed by the CSP 410 of the pulser 302₂ and/or CSP 410 of another of the pulsers 302₀-302_{L-1} (e.g., based on an inbound quantum element readout signal AI₂ demodulated by a CSP 410).

In block 614, pulser 302₂ signals to pulse operations manager 356, via signal ops_slct₂, that it wants to modify raw outbound pulse CP′_{2,T2} with pulse modification settings stored in 504₇.

In block 616, pulse modification manager 356 routes the settings from pulse modification settings circuit 5047 to pulse modification circuit 508₂.

In block 618, pulse modification circuit 508₂ processes CP′_{2,T2} using the settings received in block 616. The result is output outbound quantum pulse CP_{2,T2}.

In block 620, as directed by pulser 302₂, output manager 360 routes CP_{2,T2} to signal path 313₇ (as signal DO₇).

Thus, at different times during runtime of a single quantum algorithm, a single pulser 302 generates pulses for two different paths (which may correspond to two different quantum elements 122 of the quantum processor 202, in this example), and each of the pulses receives different processing that is customized for its respective path and/or quantum element.

In accordance with an example implementation of this disclosure, a quantum controller (e.g., 210) comprises raw pulse generation circuitry (e.g., one or more pulsers 302), pulse modification circuitry (e.g., 356 and 358), and output management circuitry (e.g., 360). The raw pulse generation circuitry (e.g., 302₁) is operable to generate a raw pulse (e.g., CP_{1,T1}). The output management circuitry is operable to route one or more output pulses (e.g., one or more of CP₀-CP_{L-1}) onto a selected one or more of a plurality of signal paths (e.g., one or more of 313₀-313_{K-1}) based on to which one or more of a plurality of elements of a quantum processor (e.g., quantum elements 122₀-122_{K-1} of quantum processor 218) the one or more output pulses are to be sent. The pulse modification circuitry is operable to select one or more pulse modification settings (e.g., stored in one or more of 504₀-504_{L-1}) to use for processing of the raw pulse, where the selection is based on which of the plurality of signal paths are the selected one or more signal paths (e.g., 313₄ may be the selected signal path) and/or to which of the one or more of the plurality of elements of the quantum processor the one or more output pulses are to be sent. The pulse modification circuitry is operable to process the raw pulse using the selected one or more pulse modification settings to generate the one or more output pulses. The one or more output pulses may comprise a first output pulse generated via a first of the one or more pulse modification settings and a second output pulse generated via a second of the one or more pulse modification settings. The first of the one or more pulse modification settings may be selected based on a first of the one or more signal paths (e.g., CP_{1,T1} generated using settings from 504₃ based on the pulse being intended for 313₃), and the second of the one or more pulse modification settings may be selected based on a second of the one or more signal paths to which the second output pulse is to be transmitted (e.g., CP_{1,T2} generated using settings from 504₄ based on the pulse being intended for 313₄). The first of the one or more pulse modification settings may be selected based on characteristics (e.g., frequency, phase, etc.) of a first of the plurality of elements of the quantum processor (e.g., CP_{1,T1} generated using settings from 504₃ based on the pulse being intended for quantum element 122₃), and the second of the one or more pulse modification settings may be selected based on characteristics (e.g., frequency, phase, etc.) of a second of the plurality of elements of the quantum processor (e.g., CP_{1,T2} generated using settings from 504₄ based on the pulse being intended for 122₄). The processing of the raw pulse using the one or pulse modification settings may result in an output pulse at a different carrier frequency than the raw pulse. The processing of the raw pulse using the one or more pulse modification settings may result in a frame of reference of the one or more output pulses being rotated with respect to a frame of reference of the raw pulse. The processing of the raw pulse using the one or more pulse modification settings may adjust a phase, frequency, and/or amplitude of the raw pulse to compensate for errors introduced by the selected one or more signal paths (e.g., in 362). The quantum controller may comprise input management circuitry (e.g., 352) operable to receive quantum element readout pulses (e.g., RP₀-RP_{M-1}) from a plurality of quantum elements, and route each of the quantum element readout pulses to one or more of a plurality of inputs of the raw pulse generation circuitry (e.g., as one or more of A₀-A_{L-1}), wherein the one or more inputs are dynamically determined during execution of instructions of a quantum computing algorithm by the quantum controller. The pulse modification circuitry may be operable to store a plurality of pulse modification settings (e.g., in 504₀-504_{L-1}). The pulse modification circuitry may be dynamically configurable such that which of the plurality of pulse modifications settings are applied to the raw pulse is selectable during execution of instructions of a quantum computing algorithm by the quantum controller. Each pulse modification setting of the plurality of pulse modification settings may be configured for use with a respective signal path of the plurality of signal paths (e.g., settings in 504₀ may be tailored for signal path 313₀ and settings in 5041 may be tailored for signal path 313₁).

As used herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As used herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As used herein, the term “exemplary” means serving as a non-limiting example, instance, or illustration. As used herein, the terms “e.g.,” and “for example” set off lists of one or more non-limiting examples, instances, or illustrations. As used herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.). As used herein, the term “based on” means “based at least in part on.” For example, “x based on y” means that “x” is based at least in part on “y” (and may also be based on z, for example).

The present method and/or system may be realized in hardware, software, or a combination of hardware and software. The present methods and/or systems may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1-20. (canceled)

21. A system comprising:
a pulse generation circuit configured to adaptively determine a pulse and a routing signal during an operation of a quantum algorithm; and
a management circuit configured to route the pulse to a first quantum element according to the routing signal.

22. The system of claim 21, wherein the management circuitry is configured to route the pulse during a runtime of the quantum algorithm.

23. The system of claim 21, wherein the pulse is adaptively determined according to a characteristic of a readout pulse received from a second quantum element.

24. The system of claim 21, wherein the routing signal is generated according to one or more calculations performed by the pulse generation circuit.

25. The system of claim 21, wherein the pulse generation circuit comprises a raw pulse generation circuit and a pulse modification circuit.

26. The system of claim 25, wherein:
the pulse modification circuit is configured to store a plurality of pulse modification settings, and
each of the plurality of pulse modification settings is configured to provide a characteristic to control a controlled element.

27. The system of claim 26, wherein the pulse modification circuit is configured to determine which of the plurality of pulse modification settings to use for processing the pulse.

28. The system of claim 26, wherein each of plurality of pulse modification settings determines a phase, frequency, and/or amplitude of the pulse.

29. The system of claim 21, wherein the route is predetermined by a quantum algorithm description.

30. The system of claim 21, wherein the quantum element is one of a qubit and a readout resonator.

31. A method comprising:
adaptively determining a pulse and a routing signal during an operation of a quantum algorithm via a pulse generation circuit, and
routing the pulse, according to the routing signal, to a first quantum element via a management circuit.

32. The method of claim 31, wherein the management circuitry is configured to route the pulse during a runtime of the quantum algorithm.

33. The method of claim 31, wherein the pulse is adaptively determined according to a characteristic of a readout pulse received from a second quantum element.

34. The method of claim 31, wherein the method comprises generating the routing signal, via the pulse generation circuit, according to one or more calculations.

35. The method of claim 31, wherein the pulse generation circuit comprises a raw pulse generation circuit and a pulse modification circuit.

36. The method of claim 35, wherein the method comprises:
storing a plurality of pulse modification settings; and
providing a characteristic to control a controlled element according to a pulse modification setting of the plurality of pulse modification settings.

37. The method of claim 36, wherein the method comprises determining which of the plurality of pulse modification settings to use for processing the pulse.

38. The method of claim 36, wherein each of plurality of pulse modification settings determines a phase, frequency, and/or amplitude of the pulse.

39. The method of claim 31, wherein the route is predetermined by a quantum algorithm description.

40. The method of claim 31, wherein the quantum element is one of a qubit and a readout resonator.
